(19) United States
(12) Patent Application Publication
(10) Pub. No.: US 2014/0003019 A1
(43) Pub. Date: Jan. 2, 2014

(54) REMOTELY CONTROLLABLE OUTLET ASSEMBLY AND POWER REMOTE CONTROL DEVICE THEREOF

(71) Applicants: Wen-Lin CHEN, New Taipei City (TW); Chi-Kan LIN, New Taipei City (TW); Chung-Chi CHIANG, New Taipei City (TW)

(72) Inventors: Wen-Lin CHEN, New Taipei City (TW); Chi-Kan LIN, New Taipei City (TW); Chung-Chi CHIANG, New Taipei City (TW)

(21) Appl. No.: 13/609,309

(22) Filed: Sep. 11, 2012

(30) Foreign Application Priority Data
Jun. 28, 2012 (TW) 101212442

(51) Int. Cl. H05K 7/02

(52) U.S. Cl. 361/807

(57) ABSTRACT

A remotely controllable outlet assembly has a case, an outlet panel and a power remote control device. The outlet panel is mounted on the case. The power remote control device has a remote controller and a main control apparatus. The main control apparatus is mounted in the case and is electrically connected to a neutral wire, a live wire and an outlet of the outlet panel. The main control apparatus electrically connects or disconnects the neutral wire and the live wire to or from the outlet according to an operation command emitted from the remote controller. Therefore, the outlet is remotely controllable. The main control apparatus is embedded in the wall, so that the outlet assembly does not spoil the interior decoration of the house.

### CROSS-REFERENCE TO RELATED APPLICATIONS

This application claims the benefit of Taiwan patent application No. 101212442, filed on Jun. 28, 2012, the disclosure of which is incorporated herein in its entirety by reference.

### BACKGROUND OF THE INVENTION

1. Field of the Invention

The present invention relates to an outlet assembly and a power remote control device, and more particularly to a remotely controllable outlet assembly and a power remote control device thereof.

2. Description of Related Art

Developing intelligent house appliances receives considerable attention from the industry at present and this trend is expected to increase in the future. The main purpose of the intelligent house appliance is to realize a convenient home environment by automatizing the house appliances.

With reference to FIG. 6, a conventional built-out power remote control outlet device 80 comprises a shell 81, a plug 82, an outlet 83 and a power control module 84.

The plug 82 is mounted on the shell 81 and is adapted to connect to an outlet 70, which is mounted on a wall, to receive a power supply.

The outlet 83 is mounted on the shell 81 and is adapted to connect to a plug 91 of an electrical device 92.

The power control module 84 is mounted in the shell 81 and is electrically connected to the plug 82 and the outlet 83. The power control module 84 electrically connects or disconnects the plug 82 to or from the outlet 83 according to a remote control signal generated from a remote controller 90. When the plug 82 is electrically connected to the outlet 83, the electrical device 92 can receive the power supply.

The power remote control outlet device 80 is remotely controllable. When the electrical device 92 without remote control function is plugged to the power remote control outlet device 80, a user can manually operate the remote controller 90 to turn ON or turn OFF the electrical device 92.

However, when the power remote control outlet device 80 is plugged in the outlet 70 on the wall, the power remote control outlet device 80 protrudes from the wall, whereby a person or pet may be hurt by stumbling against the power remote control outlet device 80. In addition, when the user trips against the power remote control outlet device 80, the power remote control outlet device 80 may be dislodged from the outlet 70.

Furthermore, because the power remote control outlet device 80 mounted on the outlet 70 is exposed externally, the power remote control outlet device 80 spoils the interior decoration of the house. Hence, some customers who think highly of interior decoration cannot endure the conspicuous existence of the power remote control outlet device 80. As a result, they give up using the power remote control outlet device 80.

Although the conventional power remote control outlet device 80 is remotely controlled to provide the power supply, the power remote control outlet device 80 is inconvenient to use and spoils the interior decoration view. The market acceptance of the conventional power remote control outlet device 80 is accordingly poor.

### SUMMARY OF THE INVENTION

Because the conventional built-out power remote control outlet device is plugged in the wall and protrudes from the wall, the outlet device is inconvenient to use and spoils the interior decoration of the house. An objective of the present invention is to provide a remotely controllable outlet assembly. The remotely controllable outlet assembly is embedded in the wall instead of being protruding from the wall.

The remotely controllable outlet assembly of the present invention comprises a case, an outlet panel and a power remote control device.

The case has a space with a front opening. The case is adapted to be embedded in a wall. A neutral wire and a live wire enter the space through the case.

The outlet panel is mounted on the front opening of the case and has an outlet with a first wire connector and a second wire connector.

The power remote control device has a remote controller and a main control apparatus.

The remote controller emits an operation command.

The main control apparatus is mounted in the space of the case and has a shell, a neutral wire fixer, a live wire fixer, a neutral connection wire, a live connection wire and a power control module.

The neutral wire fixer is mounted in the shell. The neutral wire is fixed to the neutral wire fixer.

The live wire fixer is mounted in the shell. The live wire is fixed to the live wire fixer.

The neutral connection wire is electrically connected to the first wire connector of the outlet.

The live connection wire is electrically connected to the second wire connector of the outlet.

The power control module is mounted in the shell, is electrically connected to the neutral wire fixer, the live wire fixer, the neutral connection wire and the live connection wire, receives the operation command from the remote controller, electrically connects or disconnects the neutral wire fixer to or from the neutral connection wire according to the operation command and electrically connects or disconnects the live wire fixer to or from the live connection wire according to the operation command.

Another objective of the present invention is to provide a power remote control device having a remote controller and a main control apparatus. The main control apparatus is remotely controlled by the remote controller to connect or disconnect an outlet to or from power wires.

An electrician or decoration worker can install the case and main control apparatus of the present invention into a wall, so that the main control apparatus of the present invention is hidden behind the wall. Because the main control apparatus is not exposed externally, the main control apparatus cannot cause a hazard such as tripping a person or pet and becoming dislodged and does not spoil the interior decoration of the house.

### BRIEF DESCRIPTION OF THE DRAWINGS

FIG. 1 is an exploded perspective view of the remote controllable outlet assembly of the present invention;

FIG. 2 is an exploded perspective view of the main control apparatus of the outlet assembly of the present invention;

FIG. 3 is a partially cross-sectional view of the main control apparatus of the outlet assembly of the present invention;

FIG. 4 is a block diagram of the power control module of the outlet assembly of the present invention;

FIGS. 5A-5E are detailed circuit diagrams of the power control module of the outlet assembly of the present invention; and

FIG. 6 is an operation view of a conventional power remote control outlet device.

### DETAILED DESCRIPTION OF THE PREFERRED EMBODIMENT

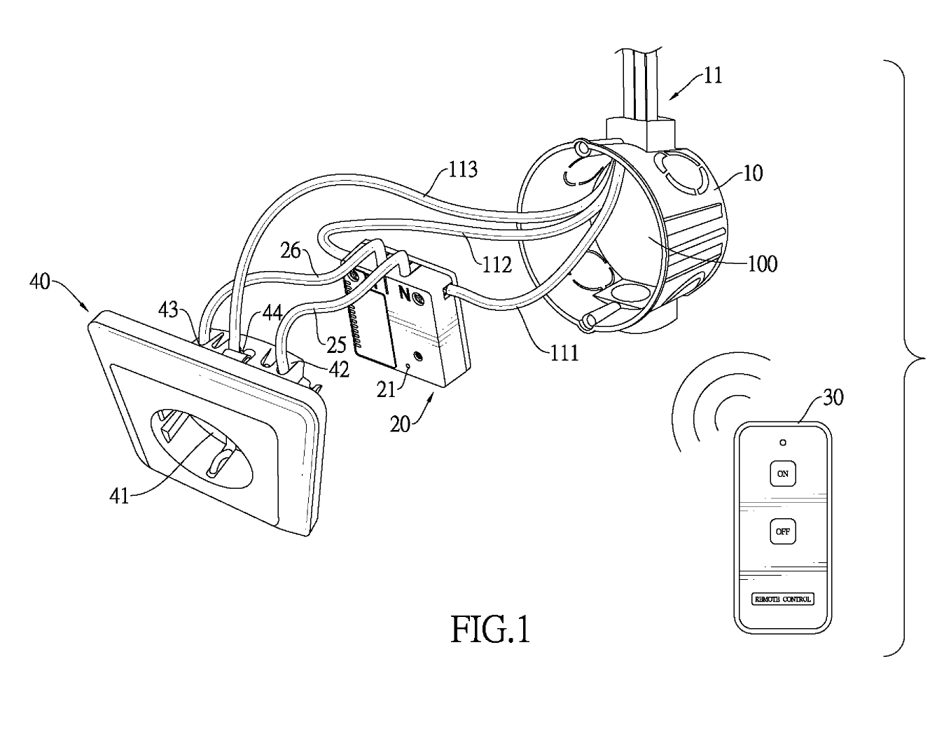

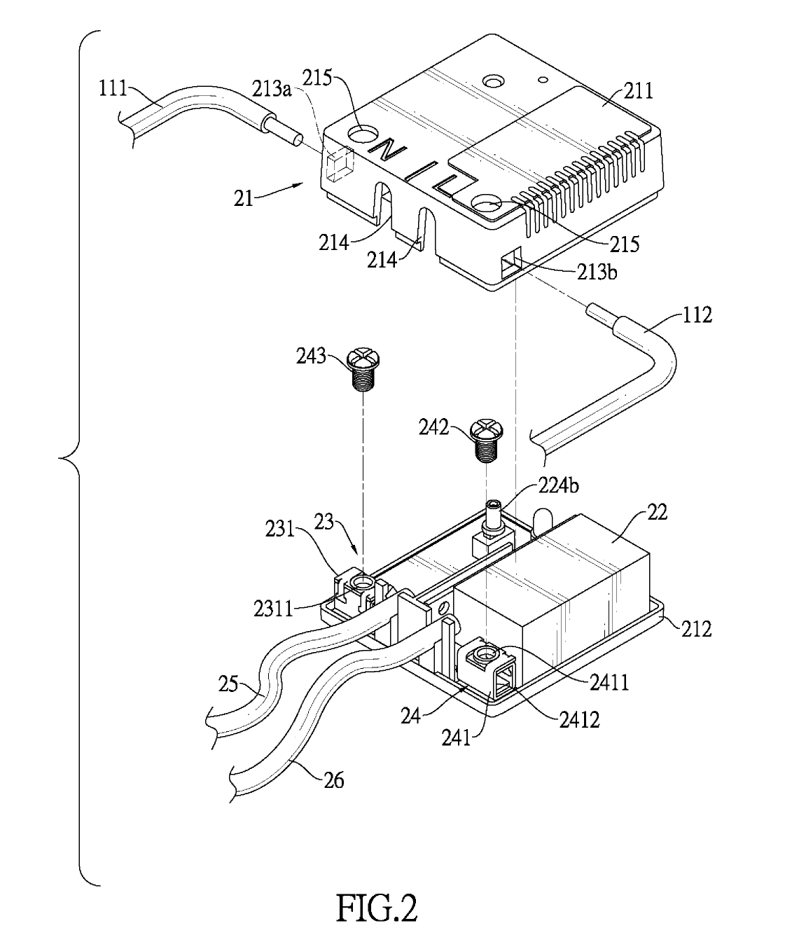

With reference to FIG. 1 and FIG. 2, a remotely controllable outlet assembly of the present invention comprises a case 10, a power remote control device and an outlet panel 40.

The case 10 has a space 100 with a front opening. In this embodiment, the case 10 is to be embedded into walls. A group of power wires 11 including a neutral wire 111, a live wire 112 and an earth wire 113 enters the space 100 through the case 10.

The power remote control device comprises a main control apparatus 20 and a remote controller 30.

The remote controller 30 emits an operation command.

The main control apparatus 20 is mounted in the space 100 of the case 10 and has a shell 21 and a power control module 22.

The shell 21 has a neutral wire fixer 23, a live wire fixer 24, a neutral connection wire 25 and a live connection wire 26. The neutral wire 111 is fixed to the neutral wire fixer 23. The live wire 112 is fixed to the live wire fixer 24.

The power control module 22 is mounted in the shell 21 and is electrically connected to the neutral wire fixer 23, the live wire fixer 24, the neutral connection wire 25 and the live connection wire 26. The power control module 22 receives the operation command output from the remote controller 30. According to the operation command, the power control module 22 can electrically connect the neutral wire fixer 23 to the neutral connection wire 25, and electrically connect the live wire fixer 24 to the live connection wire 26.

The outlet panel 40 is mounted on the front opening of the case 10 to cover the main control apparatus 20 in the space 100. The outlet panel 40 has an outlet 41 with a first wire connector 42, a second wire connector 43 and a third wire connector 44. The first wire connector 42 is electrically connected to the neutral connection wire 25. The second wire connector 43 is electrically connected to the live connection wire 26. The third wire connector 44 is electrically connected to the earth wire 113. In this embodiment, the first wire connector 42, the second wire connector 43 and the third wire connector 44 are wire holes. The neutral connection wire 25, the live connection wire 26 and the earth wire 113 are respectively and securely inserted into the connectors 42-44 to respectively and electrically connect to the connectors 42-44.

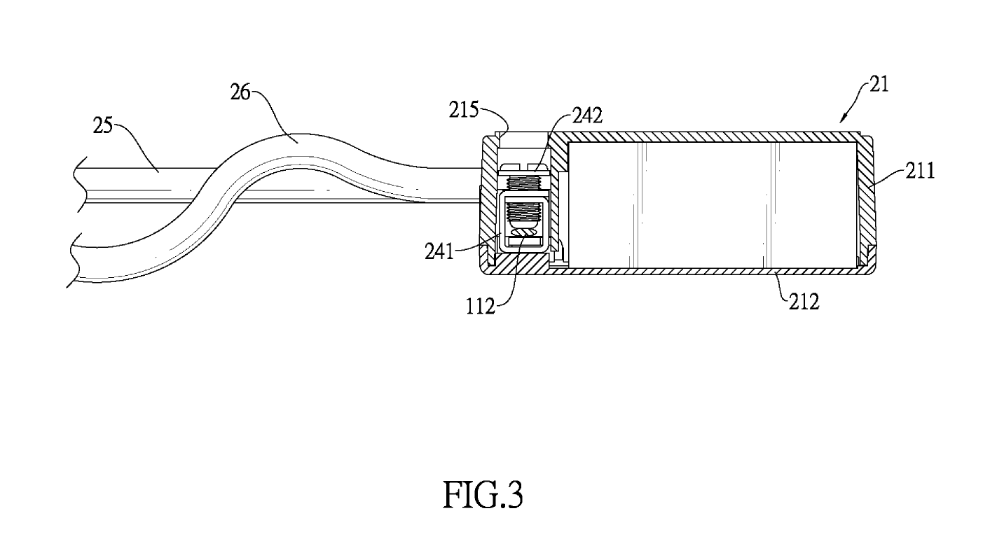

The structures of the shell 21, the neutral wire fixer 23 and the live wire fixer 24 are described below. With reference to FIG. 2 and FIG. 3, the shell 21 has a top cover 211 and a bottom cover 212.

The top cover 211 has a top surface, a first lateral surface, a second lateral surface and a third lateral surface.

The top surface has two top holes 215 separated from each other.

The first lateral surface vertically extends downward from an edge of the top surface and has a first power wire hole 213a.

The second lateral surface vertically extends downward from an edge, which is opposite to the first lateral surface, of the top surface. The second lateral surface has a second power wire hole 213b.

The third lateral surface vertically extends downward from an edge, which is situated between the first lateral surface and the second lateral surface, of the top surface. The third lateral surface has two connection wire holes 214.

The bottom cover 212 has an inner surface. The power control module 22, the neutral wire fixer 23 and the live wire fixer 24 are mounted on the inner surface of the bottom cover 212.

When the top cover 211 is mounted on the bottom cover 212, the neutral wire fixer 23 is mounted beside the first power wire hole 213a and under the top hole 215 of the top cover 211. The live wire fixer 24 is mounted beside the second power wire hole 213b and under the other top hole 215 of the top cover 211. The neutral connection wire 25 is connected between the first wire connector 42 and the power control module 22 through the connection wire hole 214. The live connection wire 26 is connected between the second wire connector 43 and the power control module 22 through the other connection wire hole 214.

The live wire fixer 24 has a metal frame 241 and a bolt 242. The metal frame 241 is mounted on the inner surface of the bottom cover 212 and has a screw hole 2411 and a via hole 2412 communicating with the screw hole 2411.

The neutral wire fixer 23 and the live neutral wire fixer 23 have the same structure. The neutral wire fixer 23 has a metal frame 231 and a bolt 232. The metal frame 231 is mounted on the inner surface of the bottom cover 212 and has a screw hole 2311 and a via hole communicating with the screw hole 2311.

When the top cover 211 is mounted on the bottom cover 212, the screw hole 2311 of the neutral wire fixer 23 is aligned with the top hole 215 of the top cover 211. The via hole of the neutral wire fixer 23 is aligned with the first power wire hole 213a of the top cover 211. The screw hole 2411 of the live wire fixer 24 is aligned with the other top hole 215 of the top cover 211. The via hole 2412 of the live wire fixer 24 is aligned with the second power wire hole 213b of the top cover 211.

The neutral wire 111 enters the via hole of the neutral wire fixer 23 through the first power wire hole 213a. The bolt 232 is screwed into the screw hole 2311 of the metal frame 231 to securely press on the neutral wire 111. Similarly, the live wire 112 enters the via hole 2412 of the live wire fixer 24 through the second power wire hole 213b. The bolt 242 is screwed into the screw hole 2411 of the metal frame 241 to securely press on the live wire 112. The bolts 232, 242 can be driven by a screwdriver which extends through the top holes 215 of the top cover 211.

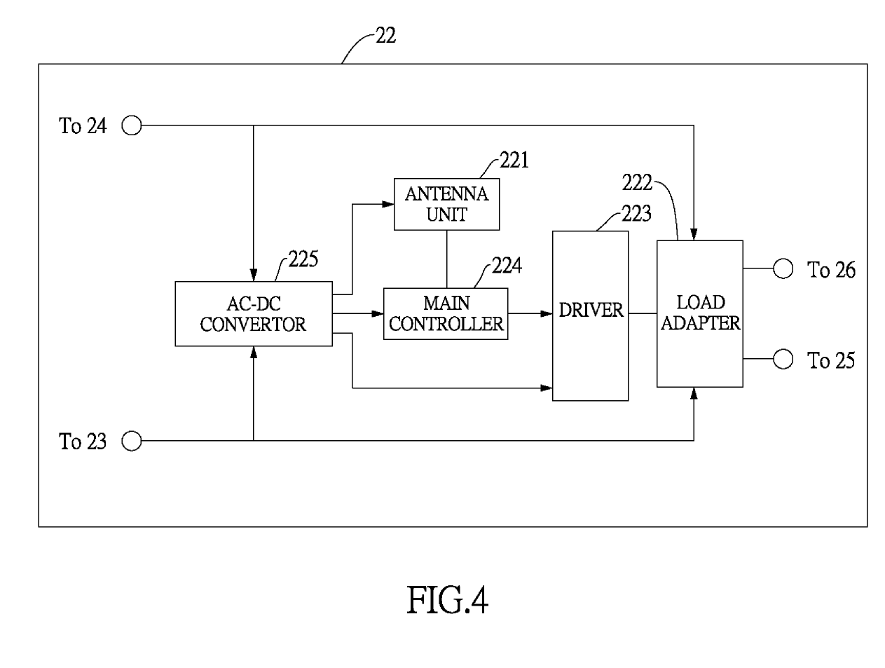

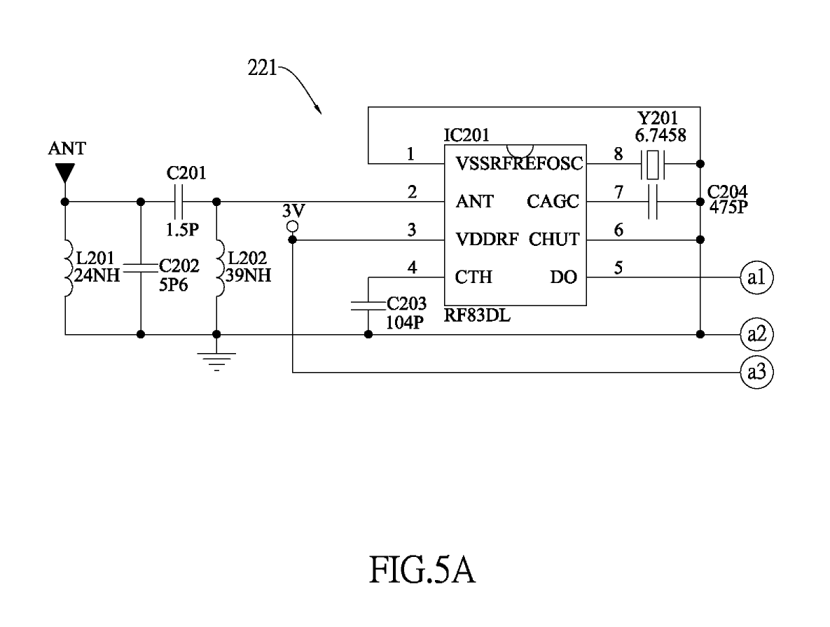

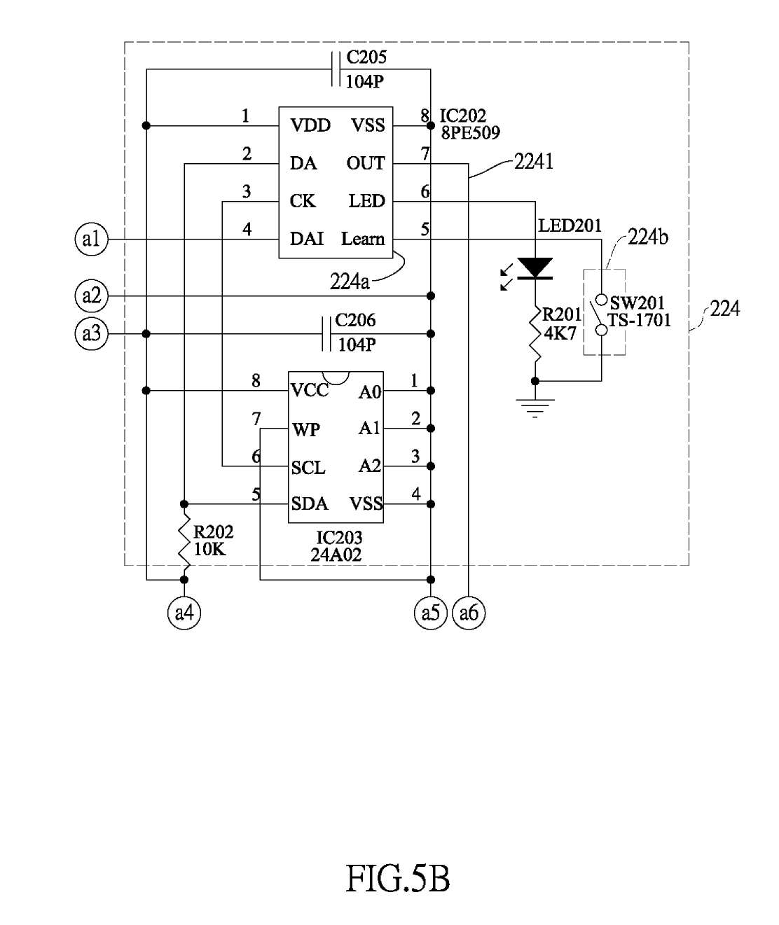

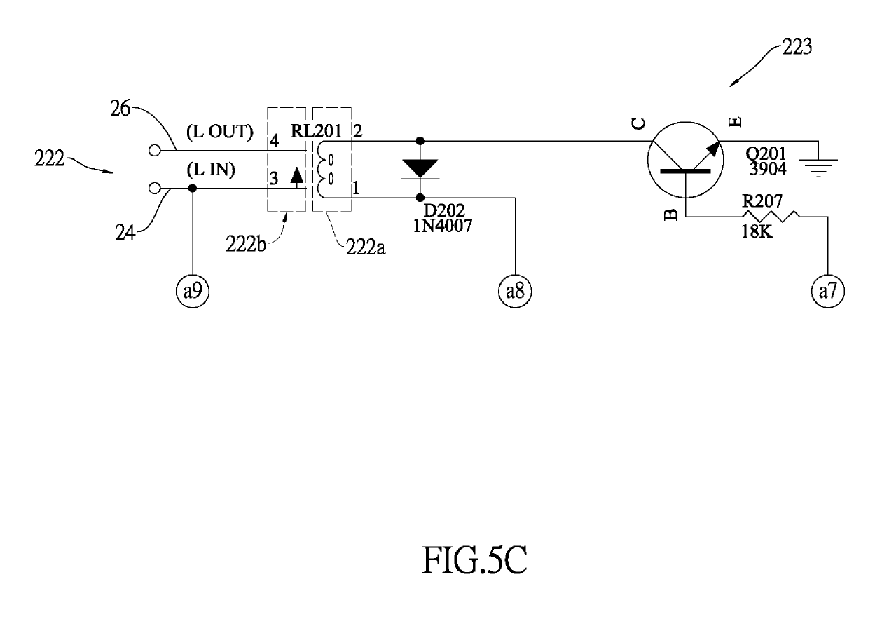

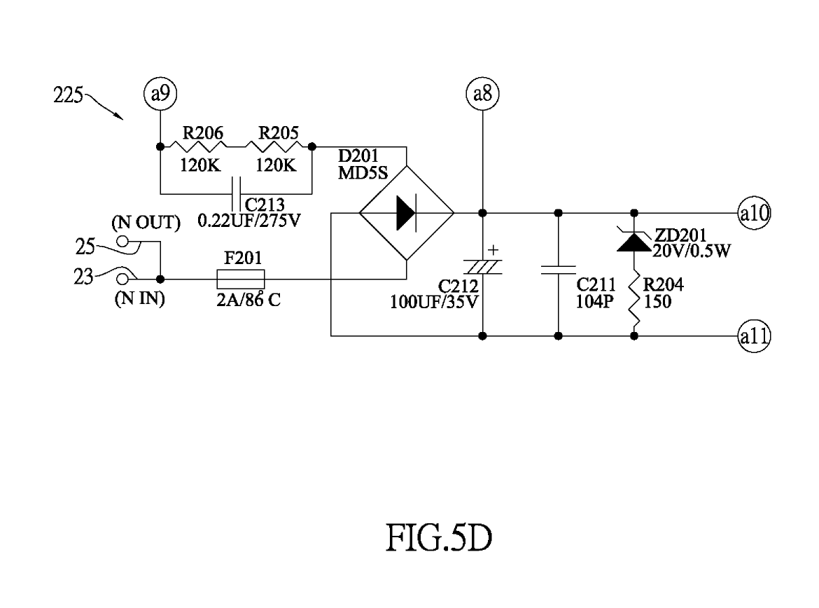

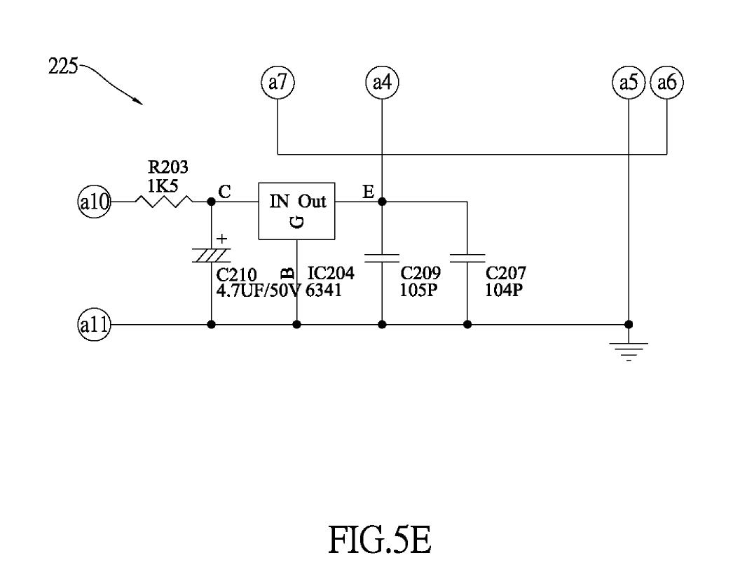

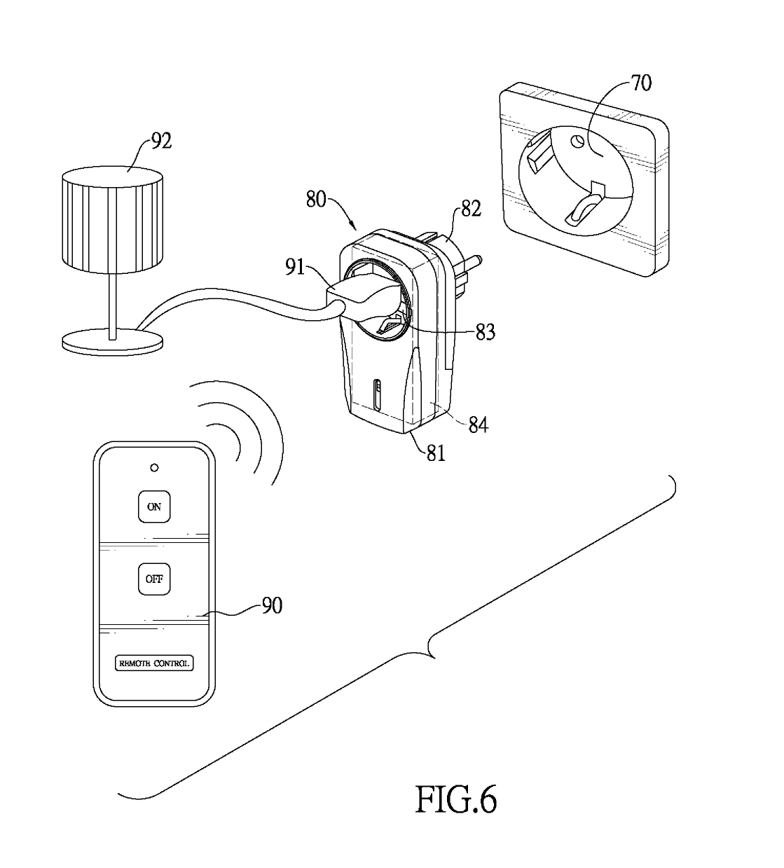

The following description relates to a detailed circuit and operation of the power remote control device. The remote controller 30 stores operation commands to control the main control apparatus 20. With reference to FIG. 4 and FIGS. 5A-5E, the power control module 22 connects the neutral wire fixer 23 to the neutral connection wire 25 and comprises an antenna unit 221, a load adapter 222, a driver 223, a main controller 224 and an AC-DC converter 225.

The antenna unit 221 wirelessly communicates with the remote controller 30 to receive the operation commands emitted from the remote controller 30.

The load adapter 222 is electrically connected to the neutral wire fixer 23, the live wire fixer 24, the neutral connection wire 25 and the live connection wire 26. The load adapter 222 is activated to connect or disconnect the live wire fixer 24 to or from the live connection wire 26. In this embodiment, the load adapter 222 is a relay of 16A maximum current. The relay is compatible for power systems of many countries, including Germany and France.

The relay has a coil 222a and a switch 222b. The switch 222b is electrically connected to the live wire fixer 24 and the live connection wire 26. The switch 222b is activated by the coil 222a to connect or disconnect the live wire fixer 24 to or from the live connection wire 26.

The driver 223 is electrically connected to the load adapter 222 to excite the coil 222a of the load adapter 222. In this embodiment, the driver 223 is a transistor having a base, a collector and an emitter. The collector is electrically connected to the coil 222a of the load adapter 222. The emitter is grounded.

The main controller 224 is electrically connected to the antenna unit 221 and the driver 223. The main controller 224 receives the operation command from the antenna unit 221 to activate the driver 223 according to the operation command. In this embodiment, the main controller 224 has a control terminal 2241. The control terminal 2241 is electrically connected to the base of the driver 223 to activate the driver 223.

The AC-DC converter 225 is electrically connected to the neutral wire fixer 23 and the live wire fixer 24 to receive an AC power. Then the AC-DC converter 225 converts the AC power to a working DC power for the antenna unit 221 and the main controller 224.

The main controller 224 further has a learning trigger terminal 224a. The learning trigger terminal 224a is electrically connected to a button 224b. When the button 224b is pressed, the main controller 224 is activated to execute a learning mode. When the main controller 224 receives a new operation command from a remote controller 30 under the learning mode, the main controller 224 stores the new operation command. Hence, each time the main controller 224 receives an operation command from a remote controller 30, the main controller 224 determines whether the present received operation command matches the stored operation command. If the presently received operation command matches the stored operation command of the main controller 224, the main controller 224 will activate the driver 223 according to the present received operation command.

With reference to FIG. 1, the case 10 of the outlet assembly of the present invention is adapted to be embedded into a wall. The main control apparatus 20 is mounted in the space 100 of the case 10. A decoration worker can fix the neutral wire 111 to the neutral wire fixer 23, fix the live wire 112 to the live wire fixer 24, fix the earth wire 113 to the third wire connector 44, insert the neutral connection wire 25 into the first wire connector 42 and insert the live connection wire 26 into the second wire connector 43.

Consequentially, the case 10 is covered by the outlet panel 40. The main control apparatus 20 of the power remote control device is hidden behind the wall and is not exposed externally. Hence, a person will not stumble against the main control apparatus 20. Moreover, the main control apparatus 20 which is hidden behind the wall does not spoil the interior decoration of the house.

In summary, the outlet 41 can be remotely controlled by the main control apparatus 20. The main control apparatus 20 is embedded in the wall. The outlet assembly of the present invention not only avoids being dislodged by a person or pet, but also does not spoil the interior decoration of the house.

What is claimed is:

1. A remotely controllable outlet assembly comprising:
a case having a space with a front opening, wherein the case is adapted to be embedded in a wall and a neutral wire and a live wire enter the space through the case;
an outlet panel mounted on the front opening of the case and having an outlet with a first wire connector and a second wire connector; and
a power remote control device having:
a remote controller for emitting an operation command; and
a main control apparatus mounted in the space of the case and having:
a shell;
a neutral wire fixer mounted in the shell, wherein the neutral wire is fixed to the neutral wire fixer;
a live wire fixer mounted in the shell, wherein the live wire is fixed to the live wire fixer;
a neutral connection wire electrically connected to the first wire connector of the outlet;
a live connection wire electrically connected to the second wire connector of the outlet; and
a power control module mounted in the shell, electrically connected to the neutral wire fixer, the live wire fixer, the neutral connection wire and the live connection wire, receiving the operation command from the remote controller, electrically connecting or disconnecting the neutral wire fixer to or from the neutral connection wire according to the operation command and electrically connecting or disconnecting the live wire fixer to or from the live connection wire according to the operation command.

2. The outlet assembly as claimed in claim 1, wherein:
the outlet of the outlet panel has a third wire connector adapted to connect to an earth wire entering the space through the case;
the first wire connector, the second wire connector and the third wire connector of the outlet are wire holes and are securely and respectively inserted by the neutral connection wire, the live connection wire and the earth wire.

3. The outlet assembly as claimed in claim 2, wherein:
the shell of the main control apparatus has:
a bottom cover;
a top cover mounted on the bottom cover and having two top holes, a first power wire hole, a second power wire hole and two connection wire holes;
the neutral wire fixer is mounted beside the first power wire hole and under the top hole of the top cover and has:
a metal frame having:
a screw hole aligned with the top hole of the top cover; and
a via hole aligned with the first power wire hole of the top cover and communicating with the screw hole; the neutral wire entering the via hole through the first power wire hole of the top cover; and
a bolt securely pressing on the neutral wire;
the live wire fixer is mounted beside the second power wire hole and under the other top hole of the top cover and has:
a metal frame having:
a screw hole aligned with the other top hole of the top cover; and
a via hole aligned with the second power wire hole of the top cover and communicating with the screw hole; the live wire entering the via hole through the second power wire hole of the top cover; and
a bolt securely pressing on the live wire;
the neutral connection wire is connected between the first wire connector and the power control module through the connection wire hole of the top cover;
the live connection wire is connected between the second wire connector and the power control module through the other connection wire hole of the top cover.

4. The outlet assembly as claimed in claim 1, wherein the power control module has:
an antenna unit wirelessly communicating with the remote controller;
a load adapter electrically connected to the neutral wire fixer, the live wire fixer, the neutral connection wire and the live connection wire, connecting the neutral wire fixer to the neutral connection wire and activated to connect or disconnect the live wire fixer to or from the live connection wire;
a driver electrically connected to the load adapter to activate the load adapter;
a main controller electrically connected to the antenna unit and the driver, receiving the operation command from the remote controller through the antenna unit and activating the driver according to the operation command; and
an AC-DC converter electrically connected to the neutral wire fixer and the live wire fixer to provide a working DC power for the antenna unit and the main controller.

5. The outlet assembly as claimed in claim 2, wherein the power control module has:
an antenna unit wirelessly communicating with the remote controller;
a load adapter electrically connected to the neutral wire fixer, the live wire fixer, the neutral connection wire and the live connection wire, connecting the neutral wire fixer to the neutral connection wire and activated to connect or disconnect the live wire fixer to or from the live connection wire;
a driver electrically connected to the load adapter to activate the load adapter;
a main controller electrically connected to the antenna unit and the driver, receiving the operation command from the remote controller through the antenna unit and activating the driver according to the operation command; and
an AC-DC converter electrically connected to the neutral wire fixer and the live wire fixer to provide a working DC power for the antenna unit and the main controller.

6. The outlet assembly as claimed in claim 3, wherein the power control module has:
an antenna unit wirelessly communicating with the remote controller;
a load adapter electrically connected to the neutral wire fixer, the live wire fixer, the neutral connection wire and the live connection wire, connecting the neutral wire fixer to the neutral connection wire and activated to connect or disconnect the live wire fixer to or from the live connection wire;
a driver electrically connected to the load adapter to activate the load adapter;
a main controller electrically connected to the antenna unit and the driver, receiving the operation command from the remote controller through the antenna unit and activating the driver according to the operation command; and
an AC-DC converter electrically connected to the neutral wire fixer and the live wire fixer to provide a working DC power for the antenna unit and the main controller.

7. The outlet assembly as claimed in claim 4, wherein:
the load adapter is a relay and has:
a coil; and
a switch being controllable by the coil to connect or disconnect the live wire fixer to or from the live connection wire;
the driver is a transistor having:
a base;
a collector electrically connected to the coil of the load adapter; and
an emitter being grounded;
the main controller has a control terminal electrically connected to the base of the driver to activate the driver.

8. The outlet assembly as claimed in claim 5, wherein:
the load adapter is a relay and has:
a coil; and
a switch being controllable by the coil to connect or disconnect the live wire fixer to or from the live connection wire;
the driver is a transistor having:
a base;
a collector electrically connected to the coil of the load adapter; and
an emitter being grounded;
the main controller has a control terminal electrically connected to the base of the driver to activate the driver.

9. The outlet assembly as claimed in claim 6, wherein:
the load adapter is a relay and has:
a coil; and
a switch being controllable by the coil to connect or disconnect the live wire fixer to or from the live connection wire;
the driver is a transistor having:
a base;
a collector electrically connected to the coil of the load adapter; and
an emitter being grounded;
the main controller has a control terminal electrically connected to the base of the driver to activate the driver.

10. The outlet assembly as claimed in claim 7, wherein:
the main controller executes a learning mode to store the operation command output from the remote controller;
when an operation command received by the main controller matches the operation command stored in the main controller, the main controller activates the driver.

11. The outlet assembly as claimed in claim 8, wherein:
the main controller executes a learning mode to store the operation command output from the remote controller;
when an operation command received by the main controller matches the operation command stored in the main controller, the main controller activates the driver.

12. The outlet assembly as claimed in claim 9, wherein:
the main controller executes a learning mode to store the operation command output from the remote controller;
when an operation command received by the main controller matches the operation command stored in the main controller, the main controller activates the driver.

13. A power remote control device comprising:
a remote controller for emitting an operation command; and
a main control apparatus having:
a shell;
a neutral wire fixer mounted in the shell, wherein a neutral wire is fixed to the neutral wire fixer;
a live wire fixer mounted in the shell, wherein a live wire is fixed to the neutral wire fixer;
a neutral connection wire;
a live connection wire; and
a power control module mounted in the shell, electrically connected to the neutral wire fixer, the live wire fixer, the neutral connection wire and the live connection wire, receiving the operation command from the remote controller, electrically connecting or disconnecting the neutral wire fixer to or from the neutral connection wire according to the operation command and electrically connecting or disconnecting the live wire fixer to or from the live connection wire according to the operation command.

14. The power remote control device as claimed in claim 13, wherein:
the shell of the main control apparatus has:
a bottom cover;
a top cover mounted on the bottom cover and having two top holes, a first power wire hole, a second power wire hole and two connection wire holes;
the neutral wire fixer is mounted beside the first power wire hole and under the top hole of the top cover and has:
a metal frame having:
a screw hole aligned with the top hole of the top cover; and
a via hole aligned with the first power wire hole of the top cover and communicating with the screw hole; the neutral wire entering the via hole through the first power wire hole of the top cover; and
a bolt securely pressing on the neutral wire;
the live wire fixer is mounted beside the second power wire hole and has:
a metal frame having:
a screw hole aligned with the other top hole of the top cover; and
a via hole aligned with the second power wire hole of the top cover and communicating with the screw hole; the live wire entering the via hole through the second power wire hole of the top cover; and
a bolt securely pressing on the live wire;
the neutral connection wire is extended through the connection wire hole of the top cover;
the live connection wire is extended through the other connection wire hole of the top cover.

15. The power remote control device as claimed in claim 13, wherein the power control module has:
an antenna unit wirelessly communicating with the remote controller;
a load adapter electrically connected to the neutral wire fixer, the live wire fixer, the neutral connection wire and the live connection wire, connecting the neutral wire fixer to the neutral connection wire and activated to connect or disconnect the live wire fixer to or from the live connection wire;
a driver electrically connected to the load adapter to activate the load adapter;
a main controller electrically connected to the antenna unit and the driver, receiving the operation command from the remote controller through the antenna unit and activating the driver according to the operation command; and
an AC-DC converter electrically connected to the neutral wire fixer and the live wire fixer to provide a working DC power for the antenna unit and the main controller.

16. The power remote control device as claimed in claim 14, wherein the power control module has:
an antenna unit wirelessly communicating with the remote controller;
a load adapter electrically connected to the neutral wire fixer, the live wire fixer, the neutral connection wire and the live connection wire, connecting the neutral wire fixer to the neutral connection wire and activated to connect or disconnect the live wire fixer to or from the live connection wire;
a driver electrically connected to the load adapter to activate the load adapter;
a main controller electrically connected to the antenna unit and the driver, receiving the operation command from the remote controller through the antenna unit and activating the driver according to the operation command; and
an AC-DC converter electrically connected to the neutral wire fixer and the live wire fixer to provide a working DC power for the antenna unit and the main controller.

17. The power remote control device as claimed in claim 15, wherein:
the load adapter is a relay and has:
a coil; and
a switch being controllable by the coil to connect or disconnect the live wire fixer to or from the live connection wire;
the driver is a transistor having:
a base;
a collector electrically connected to the coil of the load adapter; and
an emitter being grounded;
the main controller has a control terminal electrically connected to the base of the driver to activate the driver.

18. The power remote control device as claimed in claim 16, wherein:
the load adapter is a relay and has:
a coil; and
a switch being controllable by the coil to connect or disconnect the live wire fixer to or from the live connection wire;
the driver is a transistor having:
a base;
a collector electrically connected to the coil of the load adapter; and
an emitter being grounded;
the main controller has a control terminal electrically connected to the base of the driver to activate the driver.

19. The power remote control device as claimed in claim 17, wherein:
the main controller executes a learning mode to store the operation command output from the remote controller;
when an operation command received by the main controller matches the operation command stored in the main controller, the main controller activates the driver.

20. The power remote control device as claimed in claim 18, wherein:
the main controller executes a learning mode to store the operation command output from the remote controller;
when an operation command received by the main controller matches the operation command stored in the main controller, the main controller activates the driver.
